(19) United States
(12) Patent Application Publication
(10) Pub. No.: US 2013/0277033 A1
(43) Pub. Date: Oct. 24, 2013

(54) HEAT CONDUCTION STRUCTURE MOUNTED IN CASING OF ELECTRONIC PRODUCT

(71) Applicant: CHE-YUAN WU, NEW TAIPEI CITY 251 (TW)

(72) Inventor: CHE-YUAN WU, NEW TAIPEI CITY 251 (TW)

(21) Appl. No.: 13/861,606

(22) Filed: Apr. 12, 2013

(30) Foreign Application Priority Data
Apr. 18, 2012 (CN) 201220166452.3

(51) Int. Cl. H05K 7/20

(52) U.S. Cl. CPC H05K 7/20409
USPC 165/185

(57) ABSTRACT

A heat conduction structure mounted in a casing of an electronic product includes a main heat conduction module and at least one secondary heat conduction module between a heat source and the casing. The main heat conduction module includes a first heat conduction member located close to the heat source to conduct the heat of the heat source, a first heat resistant member to stop the heat from diffusing, and a heat radiation member contact with the first heat conduction member to radiate the heat. The secondary heat conduction module includes a second heat conduction member parallel to the first heat conduction member, a second heat resistant member between the first heat resistant member and the casing, a first heat radiation member and a second heat radiation member contact with the second heat conduction member to radiate the heat of the second heat conduction member.

### BACKGROUND OF THE INVENTION

1. Field of the Invention

The present invention relates to a heat conduction structure mounted in a casing of an electronic product, and more particularly to a heat conduction structure which is able to conduct the heat of a heat source evenly so as to prevent a portion of the casing at a high temperature.

2. Description of the Prior Art

A heat dissipation mechanism is mounted in a small space close to a heat source (a CPU or a power transistor). It is unable to provide a heat dissipation device (fins) on the heat source subject to the limitation of the inside space. In general, a heat conduction mechanism is provided to conduct the heat generated by the heat source to a predetermined heat sink area. As shown in FIG. 1 and FIG. 2, a conventional heat dissipation mechanism comprises a casing 60, a circuit board 71, at least one heat source 7, a heat guide pipe 8, and a conduction fixing plate 9. The casing 60 is composed of a lid 62 and a bottom board 61. The circuit board 71 is disposed in the casing 60. The heat source 7 is disposed on the circuit board 71. The heat source 7 is provided with a heat guide member 72 which has a better heat conduction efficiency. The heat guide member 72 is coupled to the heat guide pipe 8 by the conduction fixing plate 9. The heat guide pipe 8 is further connected with a heat sink assembly 82 which is composed of a heat sink 821 and a fan 822. When in use, the heat guide member 72 is to conduct the heat generated by the heat source 7 to the heat guide pipe 8 through the conduction fixing plate 9, and then the heat is dissipated through the heat sink assembly 82.

However, the space is not enough. It is hard to cooperate with the entire circuit and the power source. Some electronic products don't use a fan to dissipate the heat so the entire heat sink module is unable to generate an obvious temperature level to cause lower heat conduction efficiency. A common metal has a heat conduction effect, and the heat is conducted at uniform speed in all directions. The heat guide member 7 and the conduction fixing plate 9 made of a metallic material can conduct the heat of the heat source 7 to the heat guide pipe 8 vertically (namely, in the direction from the heat source 7 to the heat guide pipe 8) and quickly, it is unable to diffuse the heat quickly and transversely (namely, in the extension direction that the heat guide member 72 gets contact with the heat source 7) during heat conduction. The heat guide pipe 8 continuously conducts the heat to the heat sink module 82 to cause the accumulation of heat of the heat guide member 72 and the conduction fixing plate 9. The accumulated heat will direct radiate to the surrounding bottom board 62 (or the lid 62) to cause an abnormal temperature so the temperature of the entire bottom board 61 (or the lid 62) is not even.

Accordingly, the inventor of the present invention has devoted himself based on his many years of practical experiences to solve these problems.

### SUMMARY OF THE INVENTION

The primary object of the present invention is to provide a heat conduction structure mounted in a casing of an electronic product to quickly and evenly radiate the heat of a heat source. The present invention can prevent the portion of the casing, close to the heat source, at a high temperature.

In order to achieve the aforesaid object and effect, the heat conduction structure of the present invention is mounted in a casing of an electronic product and comprises a main heat conduction module. The main heat conduction module comprises at least one first heat conduction member, at least one first heat resistant member to stop the heat from diffusing, and at least one first heat resistant member to stop the heat from diffusing. The first heat conduction member has one end located close to a heat source and conducting heat of the heat source to an opposing end thereof. The first heat resistant member is disposed between the heat source and the casing. The heat radiation member is contact with the middle section of the first heat conduction member to radiate the heat of the first heat conduction member.

Preferably, the heat conduction structure further comprises a secondary heat conduction module disposed between the main heat conduction module and the casing. The secondary heat conduction module comprises at least a second heat conduction member, at least one second heat resistant member to stop the heat from diffusing, and a first heat radiation member and a second heat radiation member to radiate the heat. The second heat conduction member is parallel to the first heat conduction member. The second heat resistant member is disposed between the first heat resistant member and the casing. The first heat radiation member is contact with the middle section of the second heat conduction member corresponding in position to the heat radiation member. The second heat radiation member is contact with the middle section of the second heat conduction member corresponding to one side of the casing.

Preferably, a plurality of secondary heat conduction modules is provided between the main heat conduction module and the casing.

Preferably, the first heat conduction member is provided with a first heat sink assembly at the end far away from the heat source.

Preferably, the second heat conduction member is provided with a second heat sink assembly at an end thereof far away from the heat source.

Preferably, a heat guide member is provided between the end of the first heat conduction member and the heat source.

Preferably, at least one portion of the first heat conduction member is provided with a heat guide layer for transverse heat conduction.

Preferably, at least one portion of the second heat conduction member is provided with a heat guide layer for transverse heat conduction.

### BRIEF DESCRIPTION OF THE DRAWINGS

FIG. 1 is an exploded view of a conventional heat dissipation mechanism;

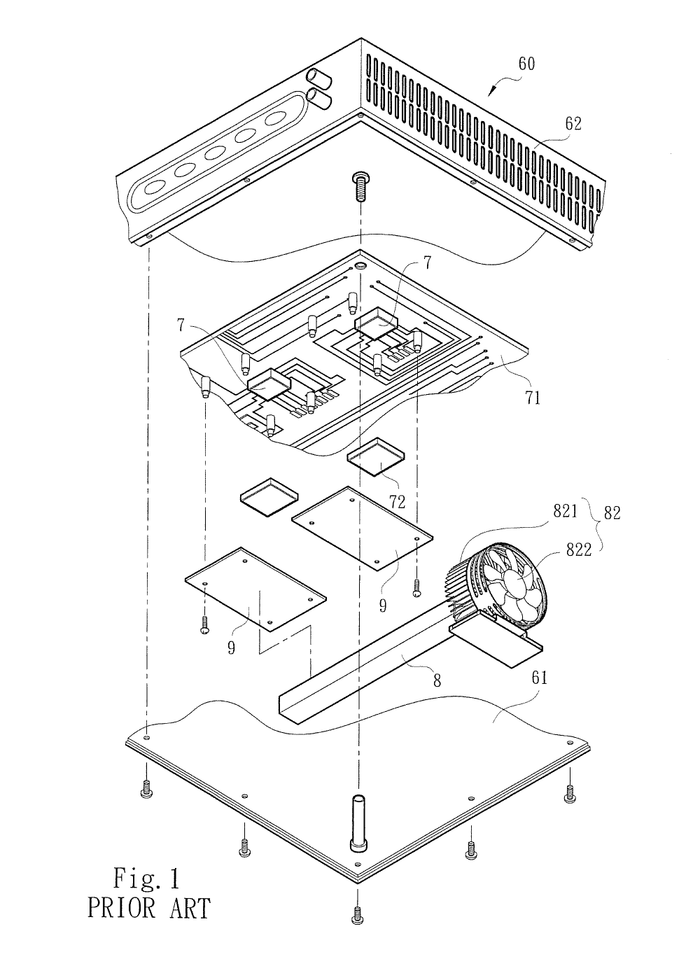

FIG. 2 is a sectional view of the conventional heat dissipation mechanism;

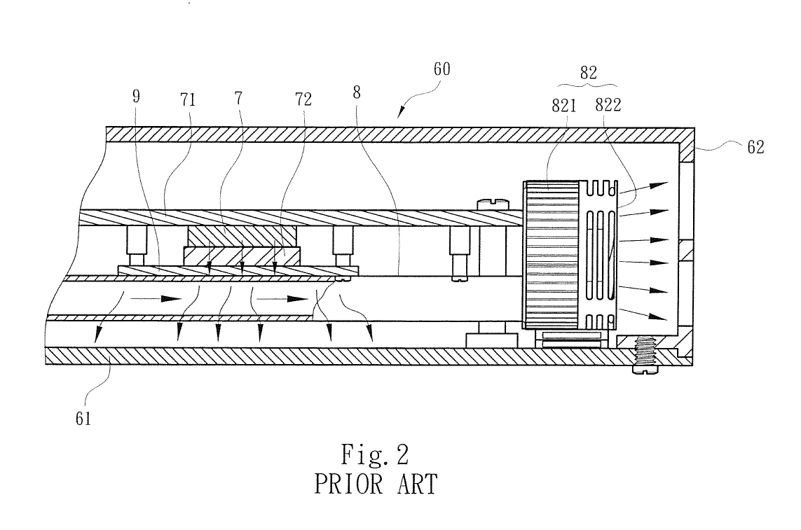

FIG. 3 is an exploded view of a first embodiment of the present invention;

FIG. 4 is a sectional view of the first embodiment of the present invention to show heat diffusion;

FIG. 5 is an exploded view of a second embodiment of the present invention;

FIG. 6 is a sectional view of the second embodiment of the present invention to show heat diffusion; and

FIG. 7 is a sectional view of a third embodiment of the present invention to show heat diffusion.

### DETAILED DESCRIPTION OF THE PREFERRED EMBODIMENTS

Embodiments of the present invention will now be described, by way of example only, with reference to the accompanying drawings.

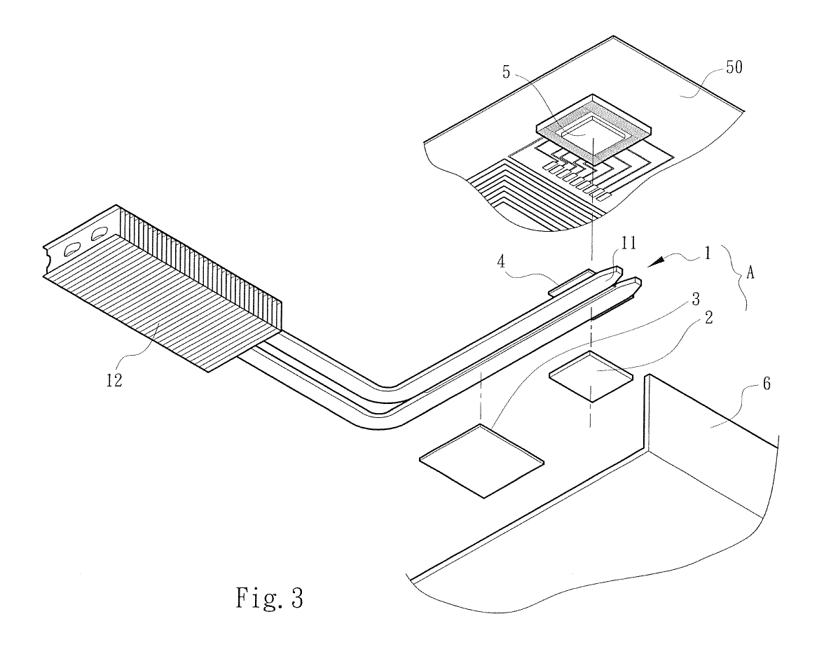

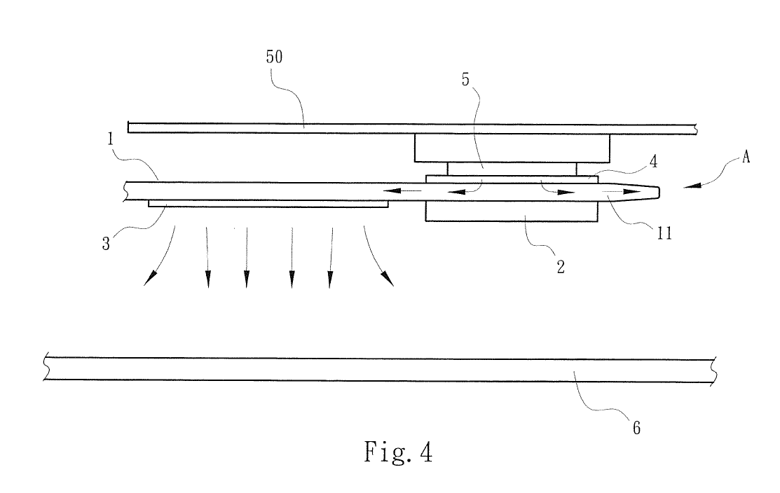

As shown in FIG. 3 and FIG. 4, the first embodiment of the present invention comprises a main heat conduction module A. The main heat conduction module A comprises a first heat conduction member 1, a first heat resistant member 2 and a heat radiation member 3. The first heat conduction member 1 is a long flat pipe. The inside of the first heat conduction member 1 is provided with a cooling medium to enhance heat exchange efficiency. One end of the first heat conduction member 1 is a first heat receiving end 11. A portion of the first heat receiving end 11 is provided with a sheet of heat guide member 4 having better heat conduction efficiency to get contact with a heat source 5 (such as a CPU, a power transistor or the like). The heat source 5 is disposed on a circuit board 50. When in use, the circuit board 50 is mounted in a casing 6. The first heat conduction member 1 is provided with a first heat sink assembly 12 (heat fins or a fan) at another end far away from the first heat receiving end 11, so that the heat of the heat source 5 can be dissipated expeditiously.

The first heat resistant member 2 is made of a material able to stop the heat from diffusing and disposed between the heat source 5 and the casing 6, preventing the heat of the heat source 5 from radiating to the inner surface of the casing 6 directly and quickly.

The heat radiation member 3 is contact with the middle section (between the first heat receiving end 11 and the first heat sink assembly 12) of the first heat conduction member 1 to radiate the heat of the first heat conduction member quickly 1 so as to lower the temperature of the first heat conduction member 1 quickly.

Thus, the aforesaid embodiment of the present invention has a heat dissipation guide function and stops the heat from radiating to the casing 6 to cause that the temperature of a portion of the casing 6 is too high.

In the aforesaid structure of the present invention, at least one portion of the first heat conduction member 1 is provided with a heat guide layer (not shown in the drawings) which has a better transverse heat conduction effect, such that the heat of the heat source can be conducted to the first heat sink assembly 12 efficiently for heat dissipation.

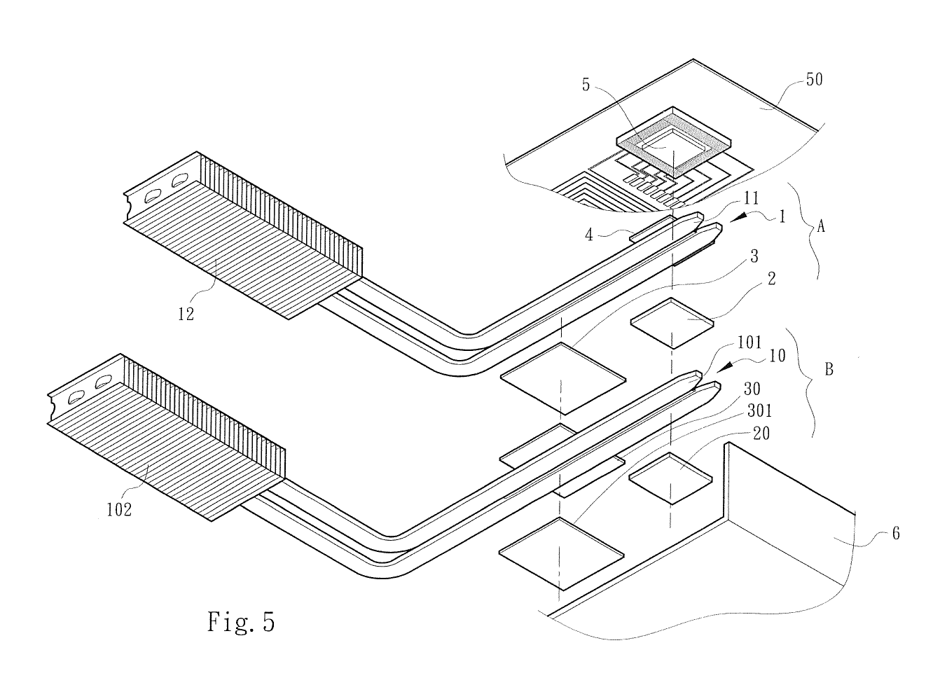

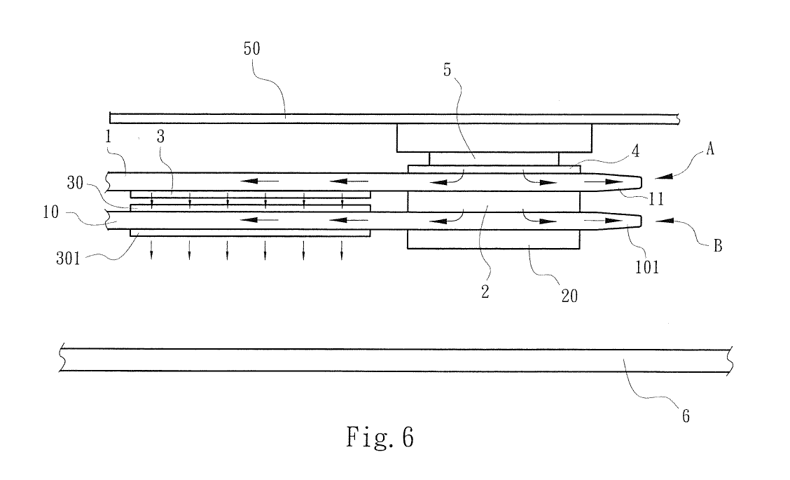

As shown in FIG. 5 and FIG. 6, the second embodiment of the present invention is modified based on the first embodiment, and comprises a main heat conduction module A as the first embodiment and a secondary heat conduction module B disposed between the main heat conduction module A and the casing 6. The main heat conduction module A comprises a first heat conduction member 1, a first heat resistant member 2 and a heat radiation member 3. The secondary heat conduction module B comprises a second heat conduction member 10, a second heat resistant member 20, a first heat radiation member 30, and a second heat radiation member 301. The second heat conduction member 10 is disposed between the first heat conduction member 1 and the casing 6, and is parallel to the first heat conduction member 1. The second heat conduction member 10 has a second heat receiving end 101 corresponding to the first heat receiving end 11. The second heat receiving end 101 is to absorb the heat of the heat source 5 from the first heat resistant member 2. The second heat conduction member 10 is provided with a second heat sink assembly 102 at another end far away from the second heat receiving end 101.

The second heat resistant member 20 is disposed between the second heat receiving end 101 and the casing 6, preventing the heat which is conducted to the second receiving end 101 through the first heat resistant member 2 from radiating to the casing 6 directly.

The first heat radiation member 30 is contact with the middle section of the second heat conduction member 10 corresponding in position to the heat radiation member 3 to absorb the heat from the heat radiation member 3. Through the second heat conduction member 10, the second heat radiation member 301 is contact with the middle section of the second heat conduction member 10 corresponding to one side of the casing 6 to radiate the heat of the second heat conduction member 10 quickly.

In the aforesaid structure of the present invention, at least one portion of the second heat conduction member 10 is provided with a layer of heat conduction (not shown in the drawings) which can enhance transverse heat conduction capability, such that the heat of the heat source can be transversely conducted to the second heat sink assembly 102 efficiently for heat dissipation.

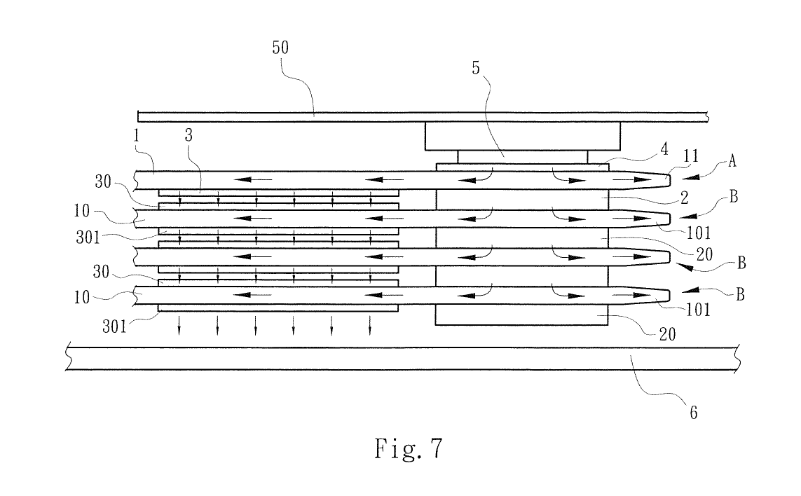

As shown in FIG. 7, the third embodiment of the present invention is modified based on the second embodiment, and comprises a main heat conduction module A as the first embodiment and a plurality of secondary heat conduction modules B disposed between the first heat conduction module A and the casing 6. The connection of the main heat conduction module A and each secondary heat conduction module B is similar to the second embodiment. This provides a better heat dissipation effect and stops the heat of the heat source 5 from directly radiating to a portion of the casing 6 at a shorter distance, preventing that the temperature of the surface the portion of the casing 6 is too high.

Accordingly, the heat conduction structure mounted in the casing of the electronic product is beneficial to radiate heat, and the heat generated by the heat source can be diffused transversely and evenly, preventing the heat from diffusing to the casing direct to cause that a portion of the casing is at a high temperature. Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A heat conduction structure mounted in a casing of an electronic product, comprising a main heat conduction module, the main heat conduction module comprising:
at least one first heat conduction member, the first heat conduction member having one end located close to a heat source and conducting heat of the heat source to an opposing end thereof;
at least one first heat resistant member to stop the heat from diffusing, the first heat resistant member being disposed between the heat source and the casing; and
at least one heat radiation member to radiate the heat, the heat radiation member being contact with a middle section of the first heat conduction member to radiate the heat of the first heat conduction member.

2. The heat conduction structure as claimed in claim 1, further comprising a secondary heat conduction module disposed between the main heat conduction module and the casing, the secondary heat conduction module comprising:
at least one second heat conduction member parallel to the first heat conduction member;
at least one second heat resistant member to stop the heat from diffusing, the second heat resistant member being disposed between the first heat resistant member and the casing; and
a first heat radiation member and a second heat radiation member to radiate the heat, the first heat radiation member being contact with a middle section of the second heat conduction member corresponding in position to the heat radiation member, the second heat radiation member being contact with the middle section of the second heat conduction member corresponding to one side of the casing.

3. The heat conduction structure as claimed in claim 2, wherein a plurality of secondary heat conduction modules is provided between the main heat conduction module and the casing.

4. The heat conduction structure as claimed in claim 1, wherein the first heat conduction member is provided with a first heat sink assembly at the end far away from the heat source.

5. The heat conduction structure as claimed in claim 2, wherein the first heat conduction member is provided with a first heat sink assembly at the end far away from the heat source.

6. The heat conduction structure as claimed in claim 3, wherein the first heat conduction member is provided with a first heat sink assembly at the end far away from the heat source.

7. The heat conduction structure as claimed in claim 2, wherein the second heat conduction member is provided with a second heat sink assembly at an end thereof far away from the heat source.

8. The heat conduction structure as claimed in claim 3, wherein the second heat conduction member is provided with a second heat sink assembly at an end thereof far away from the heat source.

9. The heat conduction structure as claimed in claim 1, wherein a heat guide member is provided between the end of the first heat conduction member and the heat source.

10. The heat conduction structure as claimed in claim 2, wherein a heat guide member is provided between the end of the first heat conduction member and the heat source.

11. The heat conduction structure as claimed in claim 3, wherein a heat guide member is provided between the end of the first heat conduction member and the heat source.

12. The heat conduction structure as claimed in claim 4, wherein a heat guide member is provided between the end of the first heat conduction member and the heat source.

13. The heat conduction structure as claimed in claim 5, wherein a heat guide member is provided between the end of the first heat conduction member and the heat source.

14. The heat conduction structure as claimed in claim 6, wherein a heat guide member is provided between the end of the first heat conduction member and the heat source.

15. The heat conduction structure as claimed in claim 7, wherein a heat guide member is provided between the end of the first heat conduction member and the heat source.

16. The heat conduction structure as claimed in claim 8, wherein a heat guide member is provided between the end of the first heat conduction member and the heat source.

17. The heat conduction structure as claimed in claim 1, wherein at least one portion of the first heat conduction member is provided with a heat guide layer for transverse heat conduction.

18. The heat conduction structure as claimed in claim 2, wherein at least one portion of the first heat conduction member is provided with a heat guide layer for transverse heat conduction.

19. The heat conduction structure as claimed in claim 3, wherein at least one portion of the first heat conduction member is provided with a heat guide layer for transverse heat conduction.

20. The heat conduction structure as claimed in claim 4, wherein at least one portion of the first heat conduction member is provided with a heat guide layer for transverse heat conduction.

21. The heat conduction structure as claimed in claim 5, wherein at least one portion of the first heat conduction member is provided with a heat guide layer for transverse heat conduction.

22. The heat conduction structure as claimed in claim 6, wherein at least one portion of the first heat conduction member is provided with a heat guide layer for transverse heat conduction.

23. The heat conduction structure as claimed in claim 2, wherein at least one portion of the second heat conduction member is provided with a heat guide layer for transverse heat conduction.

24. The heat conduction structure as claimed in claim 3, wherein at least one portion of the second heat conduction member is provided with a heat guide layer for transverse heat conduction.

25. The heat conduction structure as claimed in claim 7, wherein at least one portion of the second heat conduction member is provided with a heat guide layer for transverse heat conduction.

26. The heat conduction structure as claimed in claim 8, wherein at least one portion of the second heat conduction member is provided with a heat guide layer for transverse heat conduction.
